(19) United States
(12) Patent Application Publication
(10) Pub. No.: US 2009/0294807 A1
(43) Pub. Date: Dec. 3, 2009

(54) Methods of Fabricating Transistors and Structures Thereof

(76) Inventors: Jiang Yan, Newburgh, NY (US); Henry Utomo, Newburgh, NY (US); Wai-Kin Li, Poughkeepsie, NY (US)

Correspondence Address: SLATER & MATSIL LLP, 17950 PRESTON ROAD, SUITE 1000, DALLAS, TX, 75252, US

(21) Appl. No.: 12/129,494

(22) Filed: May 29, 2008

(51) Int. Cl. H01L 29/08; H01L 21/336

(52) U.S. Cl. 257/288; 438/303; 257/E29.04

(57) ABSTRACT

Methods of fabricating transistors, semiconductor devices, and structures thereof are disclosed. In one embodiment, a method of fabricating a transistor includes forming a gate dielectric over a workpiece, and forming a gate over the gate dielectric. Sidewall spacers are formed over the gate dielectric and the gate, the sidewall spacers comprising germanium oxide (GeO or GeO₂).

### TECHNICAL FIELD

The present invention relates generally to the fabrication of semiconductor devices, and more particularly to the fabrication of transistors.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

A transistor is an element that is used frequently in semiconductor devices. There may be millions of transistors on a single integrated circuit (IC), for example. A common type of transistor used in semiconductor device fabrication is a metal oxide semiconductor field effect transistor (MOSFET), as an example. A transistor typically includes a gate dielectric disposed over a channel region in a substrate, and a gate electrode formed over the gate dielectric. A source region and a drain region are formed on either side of the channel region within the substrate.

What are needed in the art are improved methods of fabricating transistors and structures thereof.

### SUMMARY OF THE INVENTION

These and other problems are generally solved or circumvented, and technical advantages are generally achieved, by preferred embodiments of the present invention, which provide novel methods of manufacturing semiconductor devices and transistors and structures thereof.

In accordance with one embodiment of the present invention, a method of fabricating a transistor includes forming a gate dielectric over a workpiece, and forming a gate over the gate dielectric. Sidewall spacers are formed over the gate dielectric and the gate. The sidewall spacers comprise germanium oxide (GeO or GeO₂).

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 7 show cross-sectional views of a semiconductor device at various stages of manufacturing in accordance with a preferred embodiment of the present invention, wherein GeO or GeO₂ is used as a sidewall spacer material on sidewalls of a gate and gate dielectric of a transistor while portions of the workpiece proximate the gate and gate dielectric are altered;

FIGS. 8 and 9 show cross-sectional views of a semiconductor device in accordance with another embodiment of the present invention, wherein first sidewall spacers are formed on sidewalls of a gate and gate dielectric of a transistor, and second sidewall spacers comprising GeO or GeO₂ are formed over the first sidewall spacers; and

FIGS. 10 through 12 show cross-sectional views of a semiconductor device in accordance with another embodiment of the present invention, wherein the novel GeO or GeO₂ sidewall spacers are implemented in the manufacturing process for an n channel metal oxide semiconductor (NMOS) field effect transistor (FET) and a p channel metal oxide semiconductor (PMOS) FET of a complementary metal oxide semiconductor (CMOS) device.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in specific contexts, namely implemented in single transistor devices and CMOS two-transistor device applications. Embodiments of the invention may also be implemented in other semiconductor applications such as memory devices, logic devices, and other applications that utilize transistor devices, for example.

Embodiments of the present invention provide novel methods of fabricating transistor devices, wherein sidewall spacers comprising GeO or GeO₂ are used in the manufacturing process. The GeO or GeO₂ sidewall spacers are easily removed and the removal process for the spacers has minimal effects on the workpiece, to be described further herein.

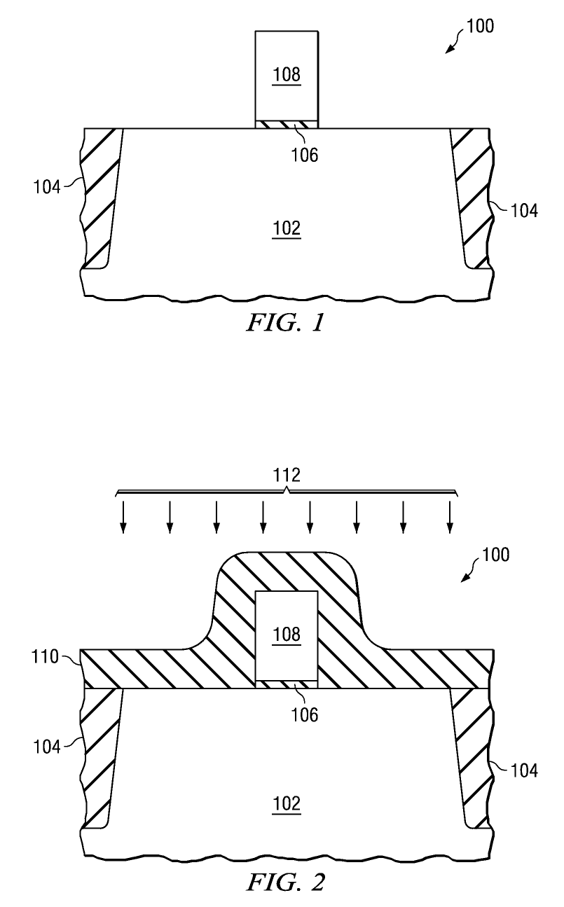

FIGS. 1 through 7 show cross-sectional views of a semiconductor device 100 at various stages of manufacturing in accordance with a preferred embodiment of the present invention. To manufacture the semiconductor device 100, first, a workpiece 102 is provided. The workpiece 102 may include a semiconductor substrate comprising silicon or other semiconductor materials and may be covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may comprise a silicon-on-insulator (SOI) or a germanium-on-insulator (GOI) substrate, as examples.

Isolation regions 104 are formed in the workpiece 102. The isolation regions 104 may comprise shallow trench isolation (STI) regions, deep trench (DT) isolation regions, field oxide isolation regions, or other insulating regions, as examples. The isolation regions 104 may be formed by depositing a hard mask (not shown) over the workpiece 102 and forming trenches in the workpiece 102 and the hard mask using a lithography process. For example, the isolation regions 104 may be formed by depositing a photoresist, patterning the photoresist using a lithography mask and an exposure process, developing the photoresist, removing portions of the photoresist, and then using the photoresist and/or hard mask to protect portions of the workpiece 102 while other portions are etched away, forming trenches in the workpiece 102. The photoresist is removed, and the trenches are then filled with an insulating material such as an oxide or nitride, or multiple layers and combinations thereof, as examples. The hard mask may then be removed. Alternatively, the isolation regions 104 may be formed using other methods and may be filled with other materials.

A gate dielectric material 106 is deposited over the workpiece 102 and the isolation regions 104. The gate dielectric material 106 may comprise about 20 nm or less of an oxide such as SiO₂, a nitride such as Si₃N₄, a high-k dielectric material having a dielectric constant greater than 3.9, or combinations and multiple layers thereof, as examples. Alternatively, the gate dielectric material 106 may comprise other dimensions and materials, for example. The gate dielectric material 106 may be formed using thermal oxidation, chemical vapor deposition (CVD), atomic layer deposition (ALD), metal organic chemical vapor deposition (MOCVD), physical vapor deposition (PVD), or jet vapor deposition (JVD), as examples, although alternatively, other methods may also be used.

A gate material 108 is deposited over the gate dielectric material 106. The gate material 108 may comprise an electrode material. The gate material 108 may comprise a thickness of about 150 nm or less, for example. The gate material 108 may comprise a semiconductor material, such as polysilicon or amorphous silicon, a metal and/or combinations or multiple layers thereof, as examples. Alternatively, the gate material 108 may comprise other dimensions and materials, for example. The gate material 108 may be formed by CVD, PVD, or other suitable deposition methods, for example. The gate material 108 may optionally be implanted with dopants; e.g., the gate material 108 may be predoped or may be doped later, at the same time source and drain regions are implanted with dopants.

An optional hard mask (not shown) may be deposited over the gate material 108. The hard mask, if present, the gate material 108, and the gate dielectric material 106 are patterned using lithography to form a gate 108 and gate dielectric 106. For example, a layer of photosensitive material comprising a photoresist, for example, may be deposited over the gate material 108 or the hard mask. The layer of photosensitive material is patterned using lithography with the desired pattern for the gate 108 and gate dielectric 106, and the patterned layer of photosensitive material and optionally also the hard mask are used as a mask to pattern the gate 108 and the gate dielectric 106, forming a gate 108 and a gate dielectric 106 of a transistor, as shown in FIG. 1. The layer of photosensitive material and the optional hard mask are then removed.

Only one gate 108 and gate dielectric 106 is shown in the embodiment of FIGS. 1 through 7; alternatively, a plurality of gates 108 and gate dielectrics 106, e.g., of a plurality of transistors, may be formed across the surface of the workpiece 102 in some embodiments, for example.

The gates 108 may comprise a width or a gate length of about 35 to 42 nm in some embodiments, for example. The gates 108 may extend lengthwise, e.g., in and out of the paper, by about 500 nm. Alternatively, the gates 108 may comprise other dimensions depending on the particular application and the technology node used for the manufacturing of the semiconductor device 100, for example.

The workpiece 102 may be lightly doped with a dopant species to form lightly doped regions (not shown) in a top surface of the workpiece 102 proximate the gate 108 and gate dielectric 106, after the patterning of the gate 108 and the gate dielectric 106. Other implantation processes (e.g., pocket implants, halo implants, or double-diffused regions) may optionally also be performed as desired after the patterning of the gate 108 and gate dielectric 106, for example. However, in accordance with some preferred embodiments of the present invention, implantation processes may not be required.

A sidewall spacer material 110 is deposited over the gate material 108. The sidewall spacer material 110 comprises germanium oxide (GeO or GeO₂). The sidewall spacers 110 advantageously comprise GeO or GeO₂, which is a material that is easily removed, e.g., using water or deionized water. GeO or GeO₂ are soluble in water, dilute acid, or base solutions, for example. Alternatively, other methods and substances may be used to later remove the sidewall spacer material comprising the GeO or GeO₂, for example. The sidewall spacer material 112 may be substantially conformal as-deposited, as shown in FIG. 2. An optional liner may be deposited over the workpiece 102 before depositing the GeO or GeO₂ sidewall spacer material, for example, to be described further herein.

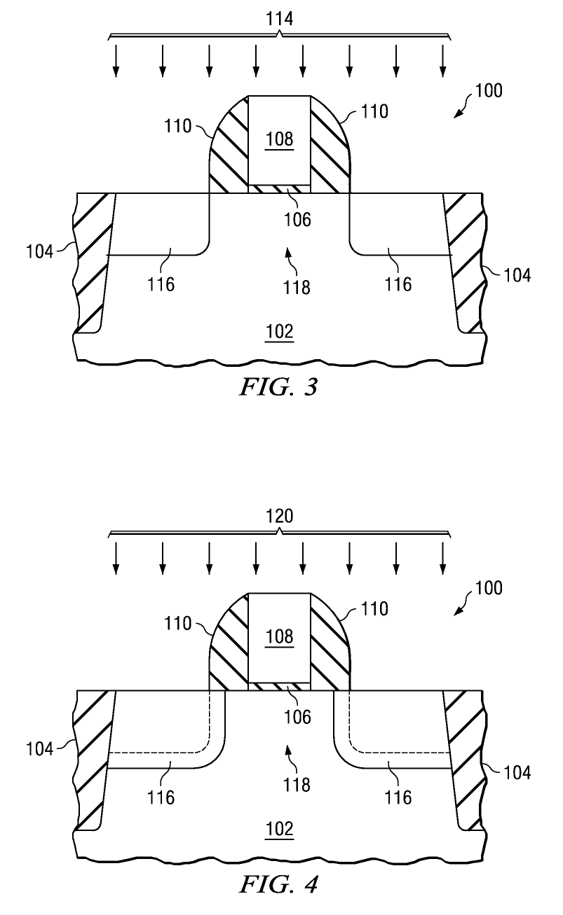

The sidewall spacer material 110 is etched using an anisotropic or directional etch process 112, as shown in FIG. 2, leaving sidewall spacers 110 on the sidewalls of the gate 108 and the gate dielectric 106, as shown in FIG. 3. The etch process 112 may comprise a reactive ion etch (RIE) etch process, for example. The etch process 112 may comprise a wet or dry etch process, or combinations thereof, for example. The anisotropic etch process 112 removes the sidewall spacer material 110 from the top surfaces of the gate 108, the workpiece 102, and the isolation regions 104, leaving sidewall spacers 110 disposed on the sidewalls of the gate 108 and gate dielectric 106. The sidewall spacers 110 may comprise downwardly-sloping sidewalls as shown due to the anisotropic etch process, for example. The sidewall spacers 110 may comprise a thickness along the sidewalls of the gate 108 proximate the workpiece 102 of about 30 nm, although alternatively, the sidewall spacers 110 may comprise other dimensions. The sidewall spacers 110 may comprise a thickness on the sidewalls of the gate 108 of about 10 to 40 nm, for example. The sidewall spacers 110 comprise temporary sidewall spacers that are later removed, for example.

After the formation of the sidewall spacers 110, which are also referred to herein as second sidewall spacers 110 (e.g., if optional first sidewall spacers are first formed on sidewalls of the gate 108 and gate dielectric 106, to be described further herein), the workpiece 102 is altered proximate the sidewall spacers 110, in accordance with embodiments of the present invention. The workpiece 102 may be implanted with a substance, or the workpiece 102 may be silicided, as examples, with the temporary sidewall spacers 110 in place, although alternatively, the workpiece 102 may be altered in other ways. In some embodiments, at least a source or drain region is altered in the workpiece 102 proximate the sidewall spacers, for example.

For example, optionally, the workpiece 102 may be subjected to an implantation process 114, as shown in FIG. 3, resulting in a deep implantation of a dopant species proximate the sidewall spacers 110, as shown at 116 in FIG. 3. The implantation regions 116 may form source and drain regions of the semiconductor device 100, for example. The gate 110 may also be implanted with a dopant species during the implantation process 114, for example. A channel region 118 is formed in the workpiece 102 beneath the gate 108, e.g., beneath the gate dielectric 106. The deep implantation regions 116 may extend within the workpiece 102 by about 100 nm to several hundred nm, as examples.

The workpiece 102 may optionally be annealed using an anneal process 120, as shown in FIG. 4. The anneal process 120 results in the driving in of the dopant species from the implantation regions 116 deeper into the workpiece 102, enlarging the source and drain regions 116, as shown in FIG. 4. In some embodiments, the workpiece 102 may alternatively not be annealed, for example. As one example, the workpiece 102 may be annealed at a temperature of about 1,000 C or greater, e.g., about 1,050 to 1,070 degrees C. for a few seconds, e.g., using a spike anneal. The anneal process 120 may cause diffusion of the dopants of the implantation regions 116 further into the adjacent workpiece 102, e.g., by about 5 nm or less, although alternatively, the anneal process 120 may cause diffusion of the dopants of greater than about 5 nm, for example.

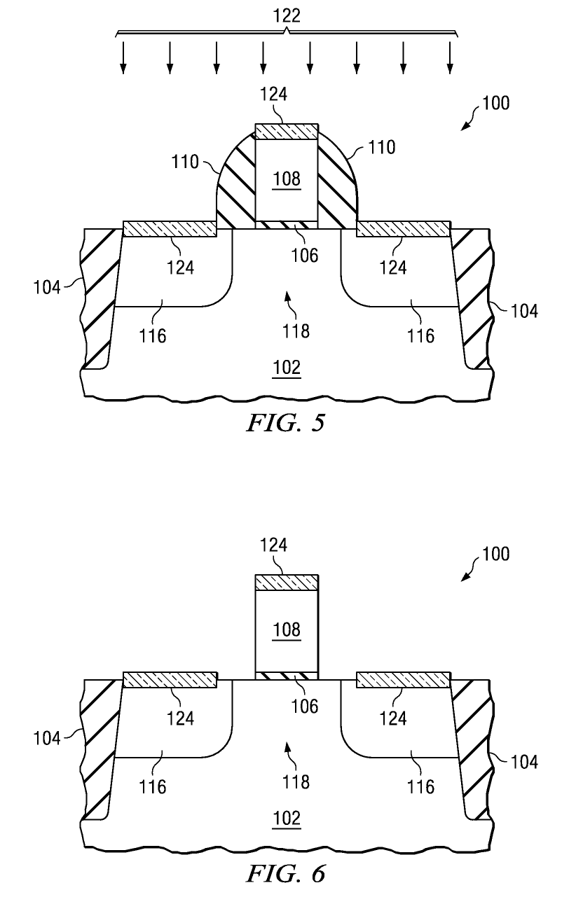

A silicide 124 may be formed on top surfaces of the gate 108 and the source and drain regions 116, as shown in FIG. 5. The silicide 124 may be formed by depositing a metal layer (not shown) such as Co, Ni, Pt, other metals or combinations thereof, on top of the isolation regions 104, the implantation regions 116, the sidewall spacers 110, and the gate 108 and heating the workpiece 102 using a heating process 122, causing a portion of the metal layer to combine with the silicon of the workpiece 102, e.g., of the implantation regions 116 and the gate 108, as shown at 124. The workpiece 102 may be heated to a temperature of about 900 to 1,000 degrees C., for example for several seconds, for example, forming the silicide 124, for example. Alternatively, other temperatures and time periods may also be used. Any unreacted metal of the metal layer may then be removed, leaving the structure shown in FIG. 5.

Before the silicide regions 124 are formed, a pre-cleaning step may be performed, e.g., using a non-dilute hydrofluoric acid (non-DHF) or in-situ cleaning step.

The silicide regions 124 improve the conductivity and reduce the resistance of the source and drain regions 116 and optionally also the gate 108, for example. The silicide 124 may partially consume the underlying semiconductive material of the workpiece 102 and the gate 108, as shown.

The sidewall spacers 110 are then removed, as shown in FIG. 6. The sidewall spacers 110 may be removed using water or deionized water in some embodiments, for example. Alternatively, the sidewall spacers 110 may be removed using an aqueous solvent, a dilute acidic solution, or a dilute basic solution, as examples. The sidewall spacers 110 advantageously comprise a material, GeO or GeO₂, that is removable using a process that is non-corrosive and has minimum effects on the workpiece 102. The removal process may comprise a water or other rinse that has minimum adverse effects on other the structures formed on the workpiece 102, advantageously. The dissolution rate of GeO₂ in de-ionized water is relatively high, for example, comprising about 100 nm/minute.

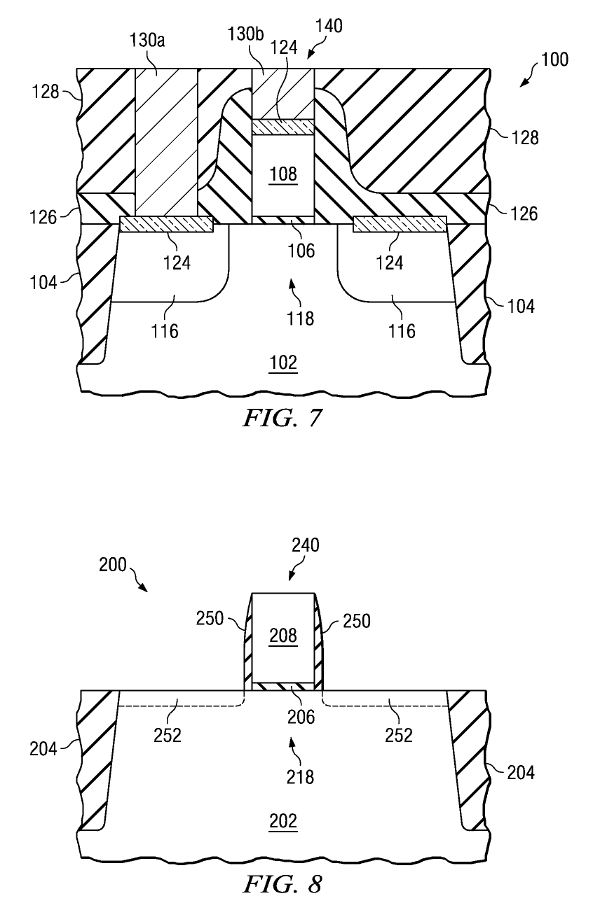

Next, the manufacturing process for the semiconductor device 100 is then continued to complete the fabrication of the transistor 140, as shown in FIG. 7. For example, an optional stress-inducing material 126 may be formed over the workpiece 102, as shown in FIG. 7. The stress-inducing material 126 may comprise a material adapted to alter a stress of the workpiece 102 in the channel region 118 of the transistor 140, e.g., disposed below the gate dielectric 106. The stress-inducing material 126 may comprise about 300 nm or less of silicon nitride, in some embodiments, for example, although other materials having other dimensions may also be used. The stress-inducing material 126 may also comprise other materials, e.g., that may or may not affect the stress of the adjacent workpiece 102. The stress-inducing material 126 may induce tensile or compressive stress to the channel region 118, for example.

Because the temporary sidewall spacers 110 are removed before the stress-inducing material 126 is formed over the workpiece 102, advantageously, the stress-inducing material 126 is placed closer to the channel region 118 and introduces more stress, improving device 100 performance.

Additional insulating material layers such as insulating material layer 128 may be formed over the stress-inducing material 126, and contacts 130a and 130b may be formed in the insulating material layer 128 and the stress-inducing material 126 to make electrical contact to the source or drain regions 116 and the gate 108, respectively. For example, contact 130a is coupled to the silicide 124 over the source or drain region 116, and contact 130b is coupled to the silicide 124 over the gate 108.

The optional stress-inducing material layer 126 may also function as a contact 130a etch stop layer for the transistor 140, for example. Insulating material 128 may comprise an interlayer dielectric (ILD) layer comprising a material such as borophosphosilicate glass (BPSG), phosphosilicate glass (PSG), silicon nitride, silicon dioxide, or plasma enhanced tetraethyloxysilane (PETEOS), as examples, although alternatively, the insulating material 128 may comprise other materials. Insulating material 128 may be etched to form contact holes using lithography, and source and drain contacts 130a and 130b may be formed through the insulating material 128 by depositing conductive material to fill the contact holes and make electrical contact to the silicided 124 source/drain regions 116 and gate 108.

Note that the semiconductor device 100 also includes metallization layers (not shown) disposed above the insulating material 128 and the source, drain, and gate contacts 130a and 130b that interconnect the various components of the semiconductor device 100. Other insulating materials and conductive materials may be formed over the transistor 140 and may be patterned to make electrical contact to portions of the transistor 140, for example, not shown. The semiconductor device 100 may be annealed to activate the dopants implanted during the various implantation steps described herein, for example.

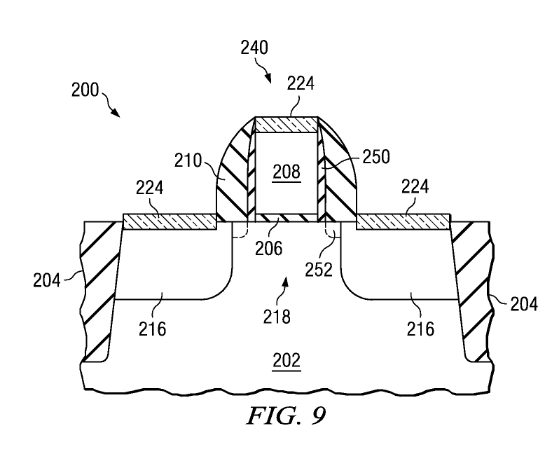

FIGS. 8 and 9 show cross-sectional views of a semiconductor device 200 in accordance with another embodiment of the present invention, wherein first sidewall spacers 250 are formed on sidewalls of the gate 208 and gate dielectric 206 of a transistor 240 in accordance with another embodiment of the present invention. Second sidewall spacers 210 comprising GeO or GeO₂ are then formed over the first sidewall spacers 250, as shown in FIG. 9. Like numerals are used for the various elements that were described in FIGS. 1 through 7. To avoid repetition, each reference number shown in FIGS. 8 and 9 is not described again in detail herein. Rather, similar element numbers x02, x04, x06, x08, etc. . . . are used to describe the various material layers shown as were used to describe FIGS. 1 through 7, where x=1 in FIGS. 1 through 7 and x=2 in FIGS. 8 and 9. As an example, the preferred and alternative materials and dimensions described for the sidewall spacer material 110 in the description for FIGS. 1 through 7 may also be used for sidewall spacer material 210 shown in FIGS. 8 and 9.

After patterning the gate 208 and gate dielectric 206, first sidewall spacers 250 may be formed by depositing an insulating material 250 over the workpiece 202, e.g., over the isolation regions 204, the gate 208 and the gate dielectric 206, as shown. The first sidewall spacers 250 may comprise an oxide, a nitride, or combinations or multiple layers thereof, as examples. The first sidewall spacers 250 may be formed by depositing the first sidewall spacer material over the workpiece 202 and anisotropically etching the first sidewall spacer material, for example. The first sidewalls spacers 250 may comprise a thickness of about 50 nm or less on sidewalls of the gate 208 and gate dielectric 206, for example, although alternatively, the first sidewall spacers 250 may comprise other dimensions.

The workpiece 202 is altered proximate the first sidewall spacers 250, as shown in FIG. 8. For example, the top surface of the workpiece 202 may be implanted using a shallow implantation process, as shown in FIG. 8 in phantom at 252. The shallow implantation regions 252 may comprise a depth within the top surface of the workpiece 202 of a few nm, for example. The shallow implantation regions 252 may comprise extension implantation regions, for example.

Next, second sidewall spacers 210 comprising GeO or GeO₂ are formed over the first sidewall spacers 250 over the gate 208 and gate dielectric 206, and the manufacturing process of the semiconductor device 200 is continued as described with reference to the embodiment shown in FIGS. 1 through 7, for example. The workpiece 202 is altered proximate the second sidewall spacers 210. Deep implantation regions 216 may be formed in the workpiece 202. The deep implantation regions 216 may extend through a portion of the shallow implantation regions 252, as shown. A silicide 224 may be formed on the top surfaces of the source and drain regions 216/252 comprising the shallow implantation regions 252 and the deep implantation regions 216, for example.

Additional material layers may then be deposited over the workpiece 202 to complete the fabrication process, as shown and described with reference to FIG. 7. A stress-inducing material such as material layer 126 may be formed over the transistor 240, for example, not shown.

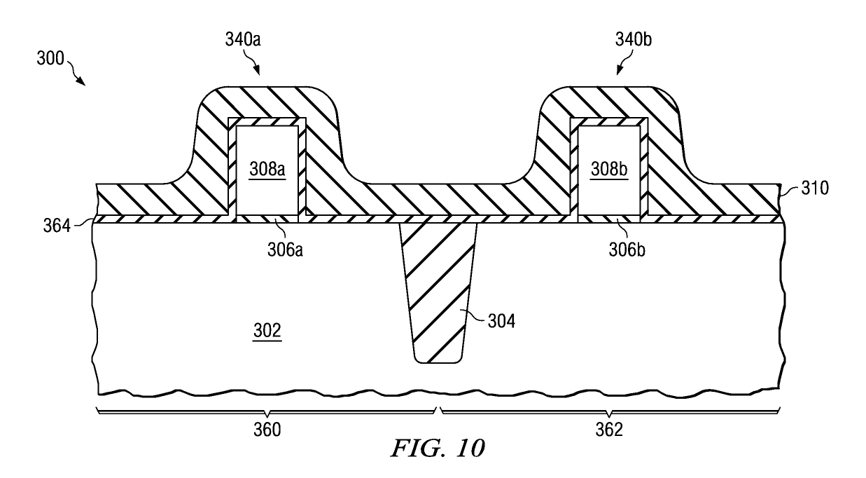

In some embodiments of the present invention, a liner 364 may be formed over the gate 308a and gate dielectric 306a before forming the sidewall spacer material 310 comprising GeO or GeO₂, as shown in FIGS. 10 through 12. FIG. 9 also illustrates an embodiment of the present invention implemented in a CMOS device, on both the PMOS FET and the NMOS FET of a CMOS device. Again, like numerals are used for the various elements in FIGS. 10 through 12 that were used to describe the previous figures, and to avoid repetition, each reference number shown in FIGS. 10 through 12 is not described again in detail herein.

Referring to FIG. 10, after forming the isolation regions 304 in the workpiece 304, a first region 360 of the workpiece 302 is masked, and the second region 362 is implanted with N wells. The second region 362 of the workpiece 302 is then masked, and the first region 360 is implanted with P wells. The gate dielectric material and the gate material are formed over the workpiece 302, and the gates 308a and 308b and the gate dielectric 306a and 306b are patterned. The workpiece 302 may alternatively be implanted with the N wells and the P wells after the gates 308a and 308b and the gate dielectric 306a and 306b are patterned, for example.

The liner 364 is then formed over the workpiece 302. The optional liner 364 may comprise an oxide material such as silicon dioxide, for example. Alternatively, the liner 364 may comprise a nitride material such as silicon nitride. The liner 364 may alternatively comprise other materials. The liner 364 may comprise a thickness of about 10 to 15 nm or less, as an example. Alternatively, the liner 364 may comprise other dimensions. The liner 364 may be formed by thermal oxidation or by CVD, as examples. The liner 364 may function as an offset spacer material for the GeO or GeO₂ 310, for example. The GeO or GeO₂ 310 is formed over the liner 364.

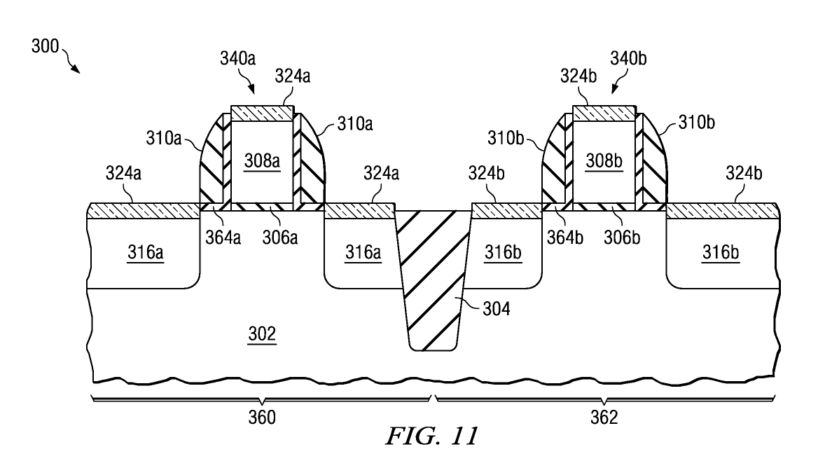

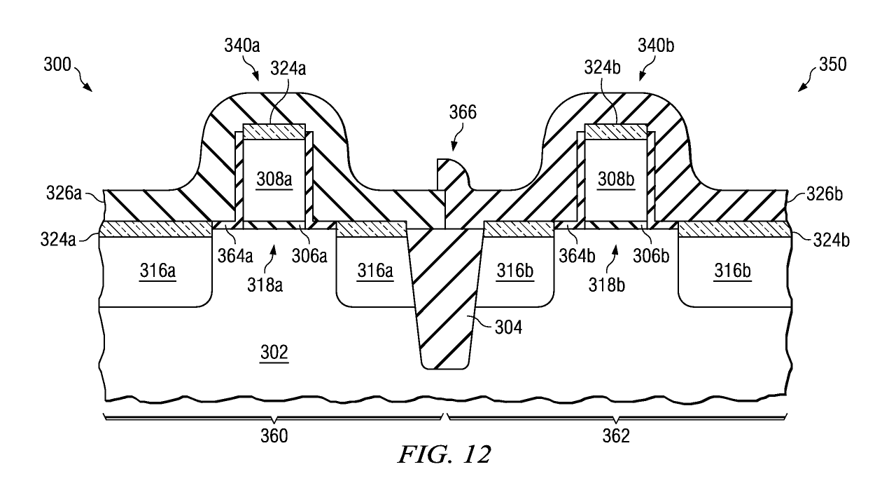

Sidewall spacers 310a/364a and 310b/364b comprising the GeO or GeO₂ 310 and the liner 364 are formed, as shown in FIG. 11, using an anisotropic or directional etch process. In the embodiment shown in FIGS. 10 through 12, a first transistor 340a is formed in a first region 360 of the workpiece 302, and a second transistor 340b is formed in a second region 362 of the workpiece 302. There may be a plurality of first transistors 340a and second transistors 340b formed across a surface of the workpiece 302, for example, not shown. A plurality of first regions 360 and second regions 362 may also be formed across the surface of the workpiece 302, for example.

With the novel sidewall spacers 310a/364a and 310b/364b residing on the sidewalls of the gates 308a and 308b and gate dielectrics 306a and 306b, the workpiece 302 proximate the sidewall spacers 310a/364a and 3110b/364b is altered. For example, deep implantation regions 316a and 316b may be formed using an implantation process, and a silicide 324a and 324b may be formed proximate the top surface of the workpiece 302, as shown in FIG. 11. Extension implantation regions may also be formed in the workpiece 302, not shown.

The first transistor 340a may comprise an NMOS FET, and the second transistor 340b may comprise a PMOS FET of a CMOS device 350, for example, in some embodiments. The first transistor 340a and the second transistor 340b may alternatively comprise other types of transistors used in multiple transistor 340a or 340b applications, for example.

After the workpiece 302 is altered with the sidewall spacers 310a/364a and 310b/364b residing on the sidewalls of the gates 308a and 308b and gate dielectrics 306a and 306b, the GeO or GeO₂ material 310a and 310b of the sidewall spacers 310a/364a and 310b/364b is removed, as shown in FIG. 12. A first stress-inducing material 326a may be deposited on the first transistor 340a, e.g., over the entire workpiece 302, and the first stress-inducing material 326a may be removed from over the second transistor 340b. A second stress-inducing material 326b may be deposited on the second transistor 340b, e.g., over the entire workpiece 302, followed by the removal of the first stress-inducing material 326b from over the first transistor 340a, as shown in FIG. 12. The second stress-inducing material 326b may overlap the first stress-inducing material 326a in an overlap region 366, as shown in FIG. 12.

The second stress-inducing material 326b may comprise a different material and may be adapted to induce a different amount or type of stress to the workpiece 302 than the first stress-inducing material 326a, for example. If the first transistor 340a comprises an NMOS FET, the first stress-inducing material 326a may be adapted to create tensile stress on the channel region 318a, which improves the performance of the NMOS FET in some applications, for example. If the second transistor 340b comprises a PMOS FET, the second stress-inducing material 326b may be adapted to create compressive stress on the channel region 318b, which improves the performance of the PMOS FET in some applications, for example. The various types of stress may be created in a nitride material such as silicon nitride used for the first and second stress-inducing materials 326a and 326b by changing the deposition temperature and various processing conditions, for example.

In some embodiments, additional nitride and/or oxide sidewall spacers (not shown in the drawings) may be used to form implantation regions of the semiconductor devices 100, before forming the novel sidewall spacers comprising germanium oxide 110, 210, 310 described herein. For example, nitride and/or oxide spacers (e.g., comprising one or more nitride and/or oxide liners) may be formed on sidewalls of the patterned gates 108, 208, 308a, and 308b and gate dielectrics 106, 206, 306a, and 306b, and at least one dopant may be implanted into the workpiece proximate the nitride and/or oxide spacers (not shown), forming implantation regions such as regions 116, 252, 216, 316a, and 316b described herein. The workpiece 102, 202, and 302 may be annealed to drive in the dopant(s) and form junctions of the transistors 140, 240, 340a, and 340b, before or after the removal of the nitride and/or oxide spacers. The removal of the nitride and/or oxide sidewall spacers may advantageously comprise a high selectivity between the nitride and oxide materials of the sidewall spacers, for example. The sidewall spacers comprising germanium oxide 110, 210, 310 are then used to form silicide 124, 224, 324a, and 324b regions, in accordance with some embodiments of the present invention. This embodiment is advantageous in applications requiring a relatively high junction anneal temperature, for example.

Note that in some embodiments, the isolation regions 104, 204, and 304 may be recessed below the top surface of the workpiece 102, 202, and 302, not shown in the drawings.

Embodiments of the present invention may be implemented in applications where single or multiple transistors are used, as described herein and shown in the figures. One example of a memory device that embodiments of the present invention may be implemented in that uses both PMOS FET's and NMOS FET's is a static random access memory (SRAM) device. A typical SRAM device includes arrays of thousands of SRAM cells, for example. Each SRAM cell may have four or six transistors (for example). A commonly used SRAM cell is a six-transistor (6T) SRAM cell, which has two PMOS FET's interconnected with four NMOS FET's. The novel methods of forming transistors and structures thereof described herein may be implemented in the transistors of SRAM devices, other types of memory devices, such as dynamic random access memory (DRAM) devices, microprocessors, mobile phone chips, digital cameras, and other types of end products, for example.

Embodiments of the present invention include methods of fabricating the semiconductor devices 100, 200, and 300 and transistors 140, 240, 340a, and 340b described herein, for example. Embodiments of the present invention also include semiconductor devices 100, 200, and 300 and transistors 140, 240, 340a, and 340b manufactured using the methods described herein.

Advantages of embodiments of the invention include providing novel methods of forming transistors 140, 240, 340a, and 340b and structures thereof. The GeO or GeO₂ spacer materials described herein are easily removable with mild removal and cleaning processes, preventing damage to the workpiece 102, 202, and 302 and other devices formed on the workpiece 102, 202, and 302. The removal of the sidewall spacer materials 110, 210, 310, 310a, and 310b is cost effective and compatible with existing semiconductor device fabrication processes, and have minimal adverse effects on other structures formed on the workpiece 102, 202, and 302. For example, the cleaning processes or removal methods used to remove the sidewall spacer materials 110, 210, 310, 310a, and 310b does not result in the removal of or damage to silicide 124, 224, 324a, and 324b, resulting in source and drain regions 116, 216/252, and 316a and 316b and gate regions 108, 208, 308a, and 308b having decreased resistance and increased conductivity.

Optional stress-inducing materials 126, 326a and 326b may be placed or positioned closer to the channel regions 118, 218, 318a, and 318b of the transistors 140, 240, 340a, and 340b, which improves the transistor 140, 240, 340a, and 340b and device 100, 200, and 300 performance.

Embodiments of the present invention are easily implementable into existing manufacturing process flows, with a small or reduced number of additional processing steps being required to fabricate the devices 100, 200, and 300, for example.

The stress-inducing materials 126, 326a and 326b cause a stress in the channels 118, 218, 318a, and 318b of the transistors 140, 240, 340a, and 340b, enhancing carrier mobility and improving the transistor 140, 240, 340a, and 340b performance. Because the GeO or GeO₂-containing sidewall spacers 110, 210, 310, 310a, and 310b comprise temporary spacer materials that are removed from the final structure, the stress-inducing materials 126, 326a and 326b may be advantageously placed closer to the channel regions of transistors 140, 240, 340a, and 340b, providing enhanced channel 118, 218, 318a, and 318b mobility and achieving improved device 100, 200, and 300 performance.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of fabricating a transistor, the method comprising:
forming a gate dielectric over a workpiece;
forming a gate over the gate dielectric; and
forming sidewall spacers over the gate dielectric and the gate, the sidewall spacers comprising germanium oxide (GeO or GeO₂).

2. The method according to claim 1, further comprising removing the sidewall spacers.

3. The method according to claim 2, wherein removing the sidewall spacers comprises using deionized water, an aqueous solvent, water, a dilute acidic solution, or a dilute basic solution.

4. The method according to claim 1, further comprising altering at least a source or drain region in the workpiece proximate the sidewall spacers.

5. The method according to claim 4, wherein altering the at least a source or drain region comprises forming a silicide.

6. The method according to claim 4, wherein altering at least the source or drain region comprises implanting at least one dopant into a workpiece proximate the sidewall spacers.

7. The method according to claim 6, further comprising annealing the semiconductor wafer, causing dopants of the doped semiconductive material of the workpiece to diffuse into the semiconductor wafer.

8. A method of manufacturing a semiconductor device, the method comprising:
providing a workpiece;
forming a gate dielectric over the workpiece;
forming a gate over the gate dielectric;
forming sidewall spacers over the gate dielectric and the gate, the sidewall spacers comprising germanium oxide (GeO or GeO₂); and
altering the workpiece proximate the sidewall spacers.

9. The method according to claim 8, further comprising forming a liner over the gate, the gate dielectric, and the workpiece, before forming the sidewall spacers.

10. The method according to claim 9, wherein forming the liner comprises forming a nitride material or an oxide material.

11. The method according to claim 8, further comprising removing the sidewall spacers, and forming a stress-inducing material over the gate and gate dielectric.

12. The method according to claim 8, wherein forming the sidewall spacers comprises depositing a layer of GeO or GeO₂ over the gate, the gate dielectric, and the workpiece, and anisotropically etching the layer of GeO or GeO₂.

13. The method according to claim 12, wherein anisotropically etching the layer of GeO or GeO₂ comprises using a reactive ion etch (RIE) process.

14. A semiconductor device manufactured in accordance with claim 8.

15. A method of manufacturing a semiconductor device, the method comprising:
providing a workpiece;
forming a gate dielectric material over the workpiece;
forming a gate material over the gate dielectric material;
patterning the gate material and the gate dielectric material to form a plurality of gates and a plurality of gate dielectrics, the plurality of gates and the plurality of gate dielectrics comprising sidewalls;
forming sidewall spacers over the sidewalls of the plurality of gates and the plurality of gate dielectrics, the sidewall spacers comprising germanium oxide (GeO or GeO₂);
altering the workpiece proximate the sidewall spacers;
removing the sidewall spacers; and
forming a stress-inducing material over the plurality of gates and the plurality of gate dielectrics.

16. The method according to claim 15, wherein removing the sidewall spacers comprises rinsing the workpiece with water or deionized water.

17. The method according to claim 15, further comprising forming first sidewall spacers on the gate dielectric and the gate, before forming the sidewall spacers over the gate dielectric and the gate, wherein forming the sidewall spacers over the gate dielectric and the gate comprises forming second sidewall spacers over the first sidewall spacers.

18. The method according to claim 17, further comprising forming shallow implantation regions in a top surface of the workpiece, after forming the first sidewall spacers, and further comprising forming deep implantation regions in the semiconductive material, after forming the second sidewall spacers.

19. The method according to claim 16, wherein patterning the gate material and the gate dielectric material comprises forming at least one first transistor comprising a p channel metal oxide semiconductor (PMOS) field effect transistor (FET) of a CMOS device and forming at least one second transistor comprising an n channel metal oxide semiconductor (NMOS) FET of the CMOS device.

20. The method according to claim 19, wherein forming the stress-inducing material comprises forming a first stress-inducing material over the PMOS FET and forming a second stress-inducing material over the NMOS FET, the second stress-inducing material comprising a different material than the first stress-inducing material.

21. The method according to claim 20, wherein forming the first stress-inducing material comprises forming a material adapted to introduce a compressive stress to a channel region of the PMOS FET, and wherein forming the second stress-inducing material comprises forming a material adapted to introduce a tensile stress to a channel region of the NMOS FET.

22. The method according to claim 15, further comprising, before forming the sidewall spacers comprising germanium oxide:
forming nitride and/or oxide spacers on sidewalls of the plurality of gates and the plurality of gate dielectrics;
implanting at least one dopant into the workpiece proximate the nitride and/or oxide spacers;
annealing the workpiece; and
removing the nitride and/or oxide spacers from the sidewalls of the plurality of gates and the plurality of gate dielectrics.

23. The method according to claim 22, wherein annealing the workpiece is before, or after removing the nitride and/or oxide spacers.
